(19) United States
(12) Patent Application Publication
(10) Pub. No.: US 2008/0181434 A1
(43) Pub. Date: Jul. 31, 2008

(54) HEADPHONE PROVIDING TONE ADJUSTING FUNCTION

(76) Inventor: Hsin-Yuan Kuo, Kaohsiung County (TW)

Correspondence Address: WPAT, PC;INTELLECTUAL PROPERTY ATTORNEYS, 2030 MAIN STREET, SUITE 1300, IRVINE, CA, 92614, US

(21) Appl. No.: 12/018,561

(22) Filed: Jan. 23, 2008

(30) Foreign Application Priority Data
Jan. 30, 2007 (TW) 096201799

(51) Int. Cl. H03G 5/02

(52) U.S. Cl. 381/98

(57) ABSTRACT

In a headphone providing tone adjusting function, a tone processing unit is utilized to process and modify the tone of a sound signal frequency characteristic, and the sound with processed tone is played via at least one play unit. The headphone further includes a tone adjustment and control unit, with which a user may adjust and control the tone processing unit to achieve the purpose of improving the tone of a received sound directly at the headphone.

### FIELD OF THE INVENTION

The present invention relates to a headphone providing tone adjusting function, and more particularly to a headphone that utilizes a tone processing unit to process and modify the tone of a sound signal frequency characteristic, so that the sound with processed tone is played via a play unit.

### BACKGROUND OF THE INVENTION

A headphone is a product being frequently used in people's daily life for receiving audio signals and listening sounds from an analog stereo system, such as a record player, a tape recorder, etc., or from a digital stereo system, such as a compact disc (CD) player, a computer, a network, or a walkman. Currently, the headphone is simply an instrument for passively play sound, and does not include any device for adjusting the tone of the received sound. While some of the currently commercially available headphones allow a user to regulate the volume of the received and played sound, they do not allow the user to adjust the tone of the received sound. When it is desired to do fine adjustment of the tone, such as setting the equalizer, the user has to operate on a signal source machine that outputs the sound signal. It is of course inconvenient for a user to do so. Even if the headphone may be directly connected to the signal source machine and play the sound without the need of an amplifier, not all the signal source machines are equipped with a tone adjusting function. In this circumstance, there is no way for the user to adjust the tone at all.

It is therefore tried by the inventor to develop a headphone having a tone processing unit and a tone adjustment and control unit, so that a user may control the adjustment of the tone of a received sound directly at the headphone without the need of operating on the signal source machine.

### SUMMARY OF THE INVENTION

A primary object of the present invention is to provide a headphone providing tone adjusting function, so that a user may adjust and control the tone of a received sound at the headphone to achieve the purpose of improving the quality of the received sound.

To achieve the above and other objects, the headphone providing tone adjusting function according to the present invention includes at least one play unit for attaching to a user's ear and playing sound; a tone processing unit for processing and modifying the tone of a sound signal frequency characteristic, and the sound with processed tone is played via the at least one play unit; and a tone adjustment and control unit for adjusting and controlling the tone processing unit.

With the tone processing unit, the tone of a sound signal frequency characteristic may be processed and modified directly at the headphone, and the sound with processed tone may be then played via the play unit. With the tone adjustment and control unit, a user may adjust and control the tone processing unit to achieve the purpose of improving the tone of the received sound directly at the headphone.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is a perspective view of a headphone providing tone adjusting function according to a first preferred embodiment of the present invention;

FIG. 2 is a perspective view of a headphone providing tone adjusting function according to a second preferred embodiment of the present invention; and

FIG. 3 is a perspective view of a headphone providing tone adjusting function according to a third preferred embodiment of the present invention.

### DETAILED DESCRIPTION OF THE PREFERRED EMBODIMENTS

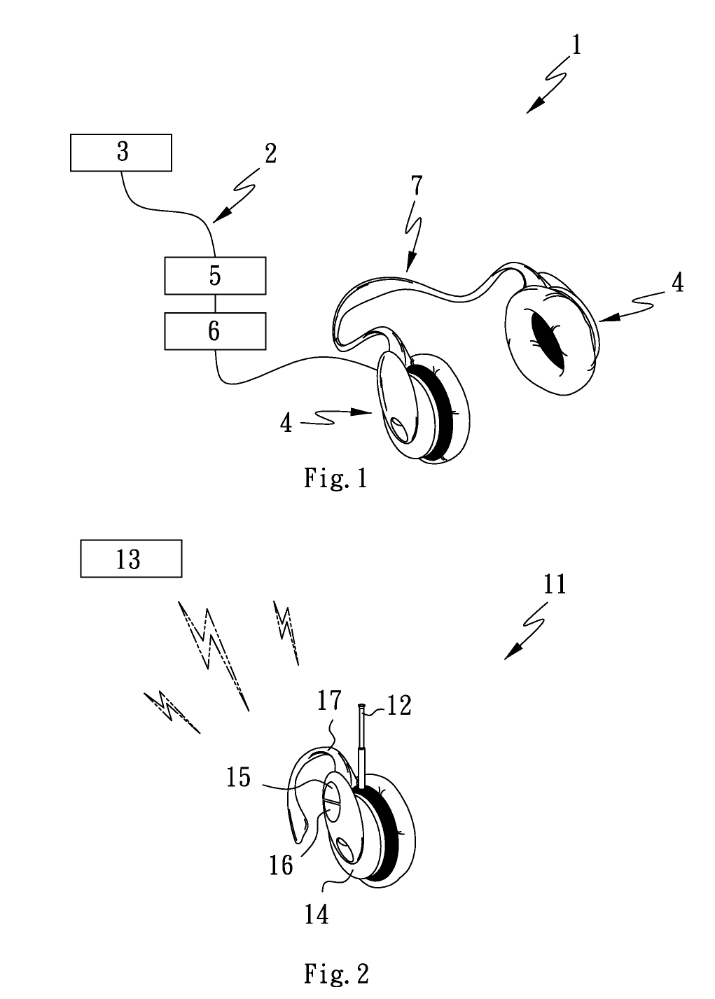

Please refer to FIG. 1. A headphone providing tone adjusting function according to a first preferred embodiment of the present invention is generally denoted a reference numeral 1 and includes a receiving unit 2, such as a wired receiving unit, for receiving a sound signal from a player unit 3; one or more play units 4, which may be attached to a user's ears (not shown) and play sound; a tone processing unit 5, including but not limited to an equalizer or a firmware stored on a read-only memory (ROM), for processing and modifying the tone of the sound signal frequency characteristic, and the sound with processed tone is played via the play units 4; a tone adjustment and control unit 6, such as at least a push key, a knob, or a slidable adjusting key, for adjusting and controlling the tone processing unit 5; and a power supply unit (not shown), such as a battery or a power plug, connected to the play units 4 and the tone processing unit 5 for supplying power needed by the play units 4 and the tone processing unit 5 to operate. The headphone providing tone adjusting function 1 further includes a fixing section 7 for attaching the headphone 1 to the user's ears.

FIG. 2 is a perspective view of a headphone providing tone adjusting function 11 according to a second preferred embodiment of the present invention. The headphone 11 includes a receiving unit 12, such as a wireless receiving unit or an antenna, for receiving a sound signal from a player unit 13; at least one play unit 14, which may be attached to a user's ear (not shown) and play sound; a tone processing unit 15, including but not limited to an equalizer or a firmware stored on a read-only memory (ROM), for processing and modifying the tone of the sound signal frequency characteristic, and the sound with processed tone is played via the play unit 14; a tone adjustment and control unit 16, such as at least a push key, a knob, or a slidable adjusting key, for adjusting and controlling the tone processing unit 15; and a power supply unit (not shown), such as a battery, connected to the play unit 14 and the tone processing unit 15 for supplying power needed by the play unit 14 and the tone processing unit 15 to operate. The headphone providing tone adjusting function 11 further includes a fixing section 17 for attaching the headphone 11 to the user's ear.

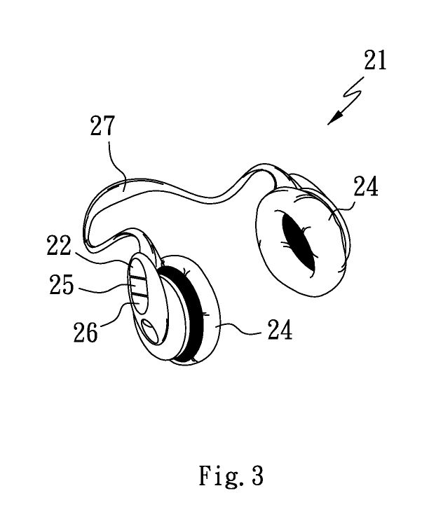

FIG. 3 is a perspective view of a headphone providing tone adjusting function 21 according to a third preferred embodiment of the present invention. The headphone 21 includes one or more play units 24, which may be attached to a user's ears (not shown) and play sound, and the sound may be played via a playing device 22 built in the headphone 21; a tone processing unit 25, including but not limited to an equalizer or a firmware stored on a read-only memory (ROM), for processing and modifying the tone of the sound signal frequency characteristic, and the sound with processed tone is played via the play units 24; a tone adjustment and control unit 26, such as at least a push key, a knob, or a slidable adjusting key, for adjusting and controlling the tone processing unit 25; and a power supply unit (not shown), such as a battery or a power plug, connected to the playing device 22, the play units 24, and the tone processing unit 25 for supplying power needed by the play units 24 and the tone processing unit 25. The headphone providing tone adjusting function 21 further includes a fixing section 27 for attaching the headphone 11 to the user's ears.

In brief, the headphone of the present invention utilizes the tone processing unit to process and modify the tone of a sound signal frequency characteristic, and the sound with processed tone is played via the play units. The present invention also includes a tone adjustment and control unit, with which a user may adjust and control the tone processing unit to thereby achieve the purpose of improving the tone of received sound directly at the headphone. The headphone providing tone adjusting function according to the present invention and other products derived from the present invention are therefore industrial valuable for use to meet the market demands.

What is claimed is:

1. A headphone providing tone adjusting function, comprising:
at least one play unit for attaching to a user's ear and playing a sound;
a tone processing unit for processing and modifying a tone of a signal frequency characteristic of the sound, and the sound with processed tone being played via the at least one play unit; and
a tone adjustment and control unit for adjusting and controlling the tone processing unit.

2. The headphone providing tone adjusting function as claimed in claim 1, further comprising a fixing section for fixing the headphone to the user's ears.

3. The headphone providing tone adjusting function as claimed in claim 1, further comprising a receiving unit for receiving a sound signal from a player unit.

4. The headphone providing tone adjusting function as claimed in claim 3, wherein the receiving unit is selected from the group consisting of a wired receiving unit and a wireless receiving unit.

5. The headphone providing tone adjusting function as claimed in claim 1, wherein the tone processing unit is an equalizer.

6. The headphone providing tone adjusting function as claimed in claim 1, wherein the tone processing unit is a firmware stored on a read-only memory (ROM).

7. The headphone providing tone adjusting function as claimed in claim 1, wherein the tone adjustment and control unit includes at least one push key.

8. The headphone providing tone adjusting function as claimed in claim 1, wherein the tone adjustment and control unit is a knob.

9. The headphone providing tone adjusting function as claimed in claim 1, wherein the tone adjustment and control unit is a slidable adjusting key.

10. The headphone providing tone adjusting function as claimed in claim 1, further comprising a power supply unit being connected to and supplying power to the at least one play unit and the tone processing unit.

11. The headphone providing tone adjusting function as claimed in claim 10, wherein the power supplying unit is a battery.

12. The headphone providing tone adjusting function as claimed in claim 10, wherein the power supplying unit is a power plug.

13. The headphone providing tone adjusting function as claimed in claim 4, wherein the wireless receiving unit is an antenna.
